(19) United States
(12) Patent Application Publication
(10) Pub. No.: US 2025/0155537 A1
(43) Pub. Date: May 15, 2025

(54) VOLTAGE MEASUREMENT SYSTEM DIAGNOSIS SYSTEM, VOLTAGE MEASUREMENT SYSTEM DIAGNOSIS METHOD, AND NON-TRANSITORY COMPUTER-READABLE RECORDING MEDIUM

(71) Applicant: Panasonic Intellectual Property Management Co., Ltd., Osaka (JP)

(72) Inventors: Mutsuhiko TAKEDA, Kyoto (JP); Shinya NISHIKAWA, Osaka (JP)

(21) Appl. No.: 18/839,520

(22) PCT Filed: Dec. 26, 2022
(86) PCT No.: PCT/JP2022/047877

§ 371 Date: Aug. 19, 2024

(30) Foreign Application Priority Data
Feb. 22, 2022 (JP) 2022-025890

(51) Int. Cl. G01R 35/00; G01R 31/3842; G01R 31/396

(52) U.S. Cl. CPC G01R 35/00; G01R 31/3842; G01R 31/396

(57) ABSTRACT

A data acquirer acquires voltage data of each cell of a battery pack in which multiple cells are connected in series or voltage data of each parallel cell block of a battery pack in which parallel cell blocks, which each include multiple cells connected in parallel, are connected in series. A judgment unit judges, when a fluctuation in a voltage of each of two cells adjacent among the multiple cells or two parallel cell blocks adjacent among the multiple parallel cell blocks exceeds a threshold, that there is an abnormality in a voltage measurement system between a connection point of the two cells or the two parallel cell blocks and a voltage measurement unit.

### CROSS-REFERENCE TO RELATED APPLICATIONS

This application is the U.S. National Phase under 35 U.S.C. § 371 of International Application No. PCT/JP2022/047877, filed on Dec. 26, 2022, which claims the benefit of foreign priority to Japan Patent Application No. 2022-025890 filed on Feb. 22, 2022, the entire contents of each of which are hereby incorporated by reference.

### BACKGROUND

### Field of the Invention

The present disclosure relates to a voltage measurement system diagnosis system, a voltage measurement system diagnosis method, and a voltage measurement system diagnosis program for detecting abnormalities in a measurement system that measures battery voltage.

### Description of the Related Art

A battery pack that contains multiple cells or parallel cell blocks (constituted by multiple cells connected in parallel) connected in series is generally equipped with a voltage measurement IC for measuring the voltage of each cell or each parallel cell block. In particular, when lithium-ion cells are used, strict voltage control is required, so that the voltage of each cell or each parallel cell block needs to be measured. In order to ensure the reliability of voltage data measured for each cell or each parallel cell block, it is necessary to check for an abnormality in voltage measurement lines that connect the multiple cells or multiple parallel cell blocks and the voltage measurement IC.

As a method for diagnosing for an abnormality in the voltage measurement lines, the following method can be considered, for example. That is, there can be considered a method of providing a circuit capable of applying a current to a voltage measurement line at predetermined timing, estimating a resistance value of a contact failure portion in a voltage measurement line based on the difference between the voltage when the current is flowing and the voltage when the current is not flowing, and judging, when the resistance value is a predetermined value or greater, that there is an abnormality (see Patent Literature 1, for example). This method uses the property of the resistance value of a contact failure portion in a voltage measurement line being greater than the resistance value of a normal portion. As the circuit for applying a current to a voltage measurement line, a discharge resistor and a discharge switch of an equalization circuit may be used.
Patent Literature 1: Japanese Unexamined Patent Application Publication No. 2018-54390

The method described above requires a circuit for applying a current to each voltage measurement line. Since a battery pack installed in an EV is usually equipped with an equalization circuit, the equalization circuit can be used to apply a current to the voltage measurement lines. However, a battery pack installed in a relatively inexpensive product, such as an electric motorcycle, an electric bicycle, or a notebook PC, is generally not equipped with an equalization circuit. In that case, a circuit for applying a current to the voltage measurement lines needs to be added separately, which increases the cost.

### SUMMARY OF THE INVENTION

The present disclosure has been made in view of such a situation, and a purpose thereof is to provide a technology for detecting, at low cost, an abnormality in a voltage measurement system of a battery pack that contains multiple cells or multiple parallel cell blocks connected in series.

To solve the problem above, a voltage measurement system diagnosis system according to one embodiment of the present disclosure includes: a data acquirer that acquires voltage data of each cell of a battery pack in which multiple cells are connected in series or voltage data of each parallel cell block of a battery pack in which parallel cell blocks, which each include multiple cells connected in parallel, are connected in series; and a judgment unit that judges, when a fluctuation in a voltage of each of two cells adjacent among the multiple cells or two parallel cell blocks adjacent among the multiple parallel cell blocks exceeds a threshold, that there is an abnormality in a voltage measurement system between a connection point of the two cells or the two parallel cell blocks and a voltage measurement unit.

Optional combinations of the aforementioned constituting elements, and implementation of the present disclosure in the form of apparatuses, systems, methods, computer programs, and the like may also be practiced as additional modes of the present disclosure.

Embodiments will now be described, by way of example only, with reference to the accompanying drawings which are meant to be exemplary, not limiting, and wherein like elements are numbered alike in several Figures, in which:

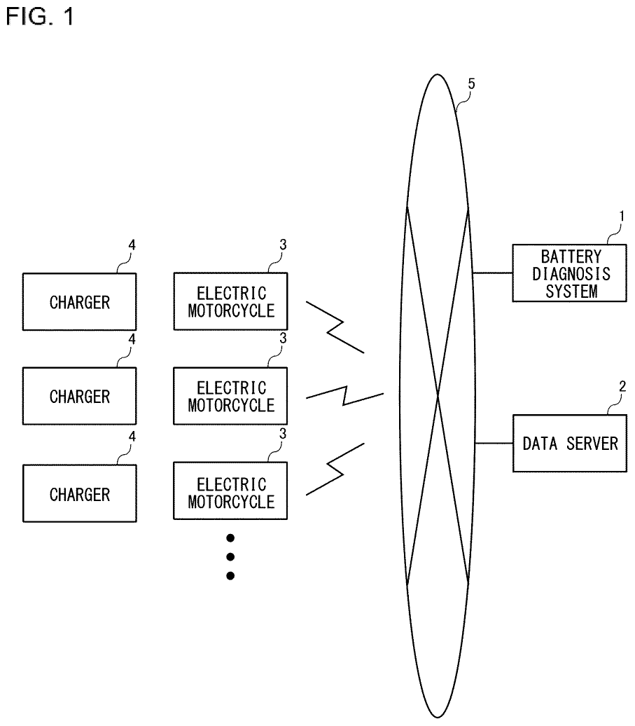

FIG. 1 is a diagram used to describe a battery diagnosis system according to an embodiment.

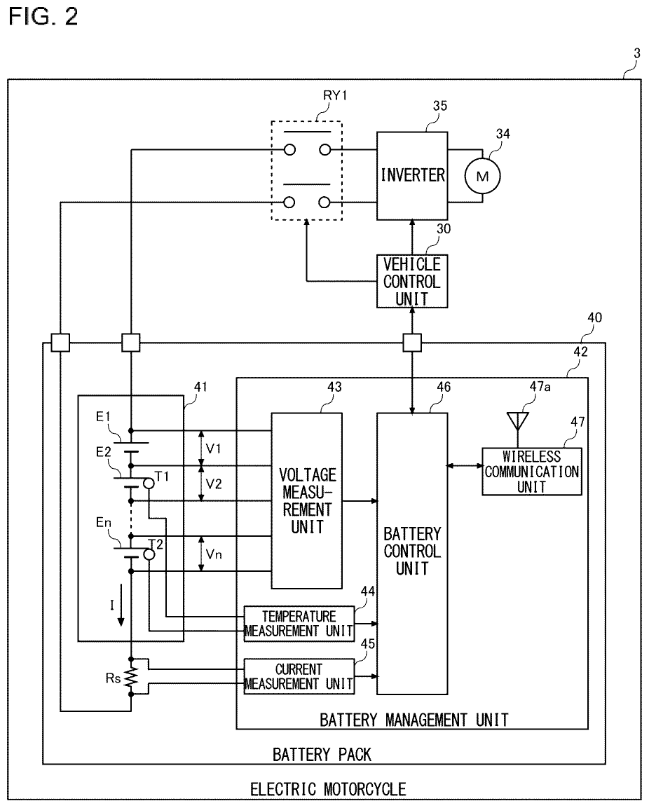

FIG. 2 is a diagram used to describe an illustrative detailed configuration of a battery pack installed in an electric motorcycle.

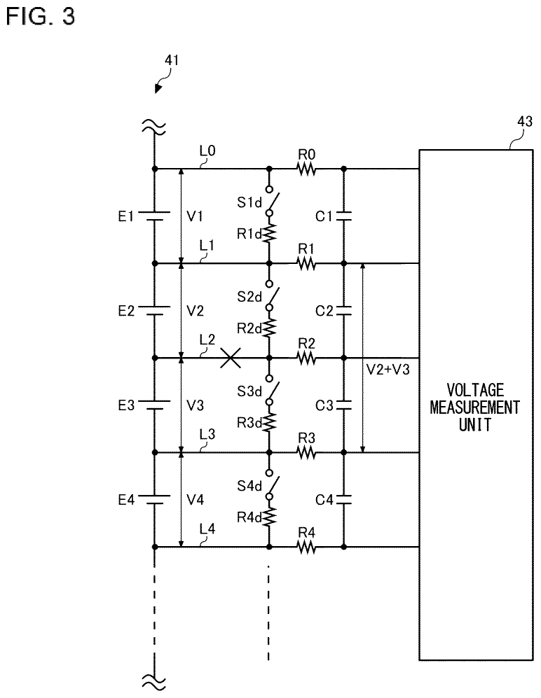

FIG. 3 is a diagram that shows an illustrative detailed configuration of voltage measurement systems between a battery module and a voltage measurement unit according to a comparative example.

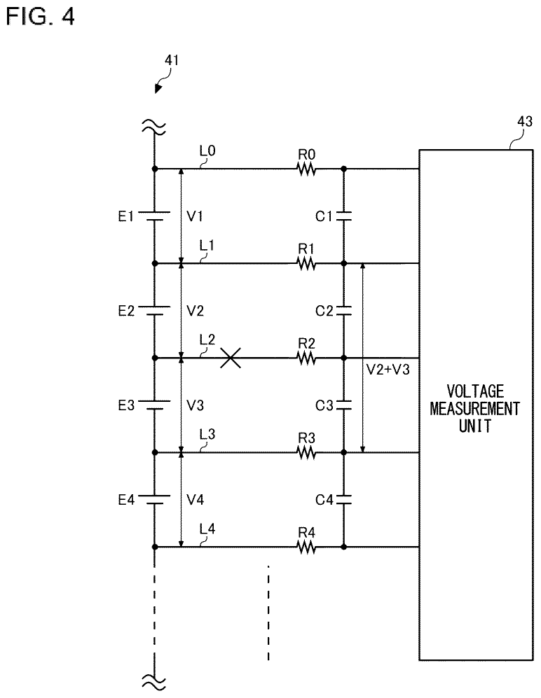

FIG. 4 is a diagram that shows an illustrative detailed configuration of voltage measurement systems between the battery module and the voltage measurement unit according to the embodiment.

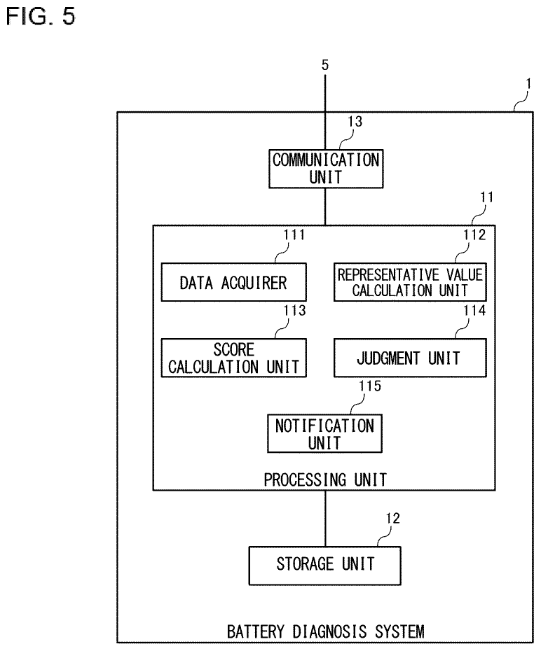

FIG. 5 is a diagram that shows an illustrative configuration of the battery diagnosis system according to the embodiment.

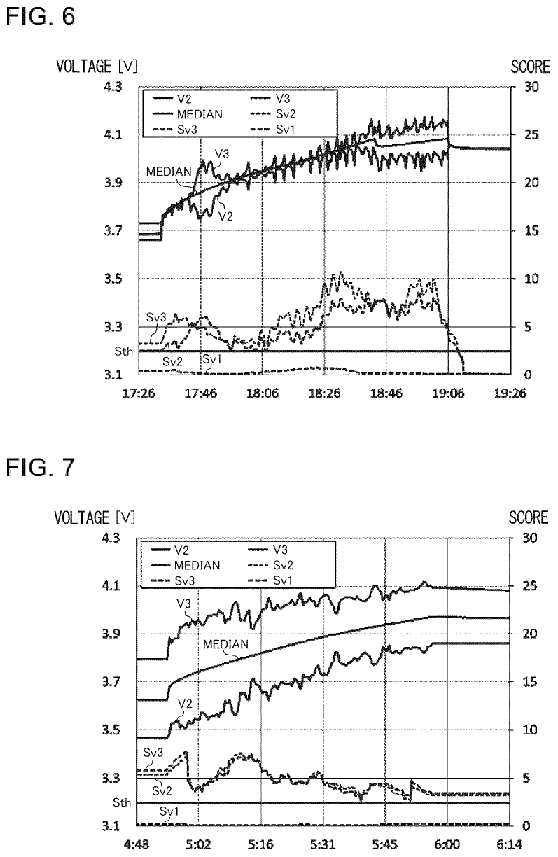

FIG. 6 is a diagram that shows actual measured data of voltage measurements and judgment scores of multiple parallel cell blocks.

FIG. 7 is a diagram that shows another actual measured data of voltage measurements and judgment scores of the multiple parallel cell blocks.

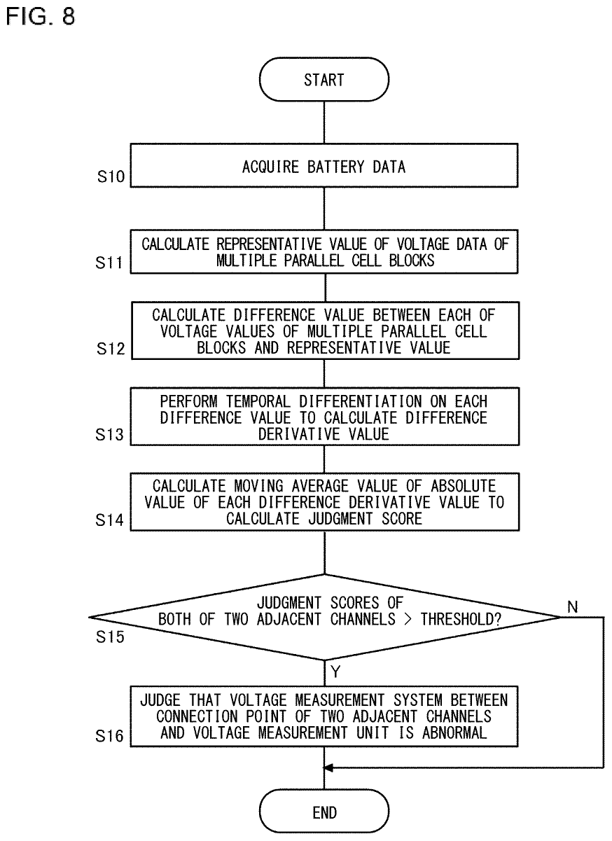

FIG. 8 is a flowchart that shows a procedure of voltage measurement system diagnosis processing performed by the battery diagnosis system according to the embodiment.

### DETAILED DESCRIPTION OF THE INVENTION

The invention will now be described by reference to the preferred embodiments. This does not intend to limit the scope of the present invention, but to exemplify the invention.

FIG. 1 is a diagram used to describe a battery diagnosis system 1 according to an embodiment. The battery diagnosis system 1 according to the embodiment includes at least a function to detect an abnormality in a voltage measurement system. The battery diagnosis system 1 according to the embodiment is a system used by an individual or a corporation using an electric motorcycle 3. For example, the system is used by a corporation that owns multiple electric motorcycles 3 and uses the multiple electric motorcycles 3 for a rental business, a sharing business, or a delivery business.

For example, for a business operator providing a battery diagnosis service, the battery diagnosis system 1 may be built on the business operator's own server installed at a facility of the business operator or a data center. Also, the battery diagnosis system 1 may be built on a cloud server used based on a cloud service contract. Also, the Battery Diagnosis System 1 can be built on s multiple servers, distributed and installed in multiple locations (such as data centers and a company's own facilities). Such multiple servers may be any of a combination of a plurality of a company's own servers, a combination of a plurality of cloud servers, and a combination of a company's own server and a cloud server.

An electric motorcycle 3 or a battery pack 40 (see FIG. 2) installed in an electric motorcycle 3 has a communication function and can connect to a network 5. The electric motorcycle 3 or battery pack 40 transmits battery data to a data server 2 via the network 5. The electric motorcycle 3 or battery pack 40 samples the battery data periodically (e.g., at intervals of 10 to 30 seconds) and transmits the sampled battery data in real time or once stores the sampled battery data in the internal memory and transmits it in batches at predetermined times.

The data server 2 acquires and stores the battery data from the electric motorcycle 3 or battery pack 40. The data server 2 may be a server of a business operator providing a battery diagnosis service or of a business operator that owns multiple electric motorcycles 3, which is installed at a facility of the business operator or a data center. The data server 2 may also be a cloud server used by a business operator providing a battery diagnosis service or by a business operator that owns multiple electric motorcycles 3. Also, both may each have a data server 2.

The network 5 is a generic term for communication channels, such as the Internet, a leased line, and a VPN (Virtual Private Network), and the communication medium or protocol thereof is not specified. As the communication medium, for example, a cellular phone network (cellular network), a wireless LAN, a wired LAN, an optical fiber network, an ADSL network, a CATV network, or the like may be used. As the communication protocol, for example, TCP (Transmission Control Protocol)/IP (Internet Protocol), UDP (User Datagram Protocol)/IP, Ethernet (registered trademark), or the like may be used.

FIG. 2 is a diagram used to describe an illustrative detailed configuration of the battery pack 40 installed in an electric motorcycle 3. In the present embodiment, the battery pack 40 is assumed to be a detachable battery pack 40 that is portable and replaceable. The battery pack 40 is attached to a mounting slot of an electric motorcycle 3 and used. Also, the battery pack 40 is attached to a charging slot of a charger 4 and charged. The battery pack 40 may also be fixed to the electric motorcycle 3. In that case, the battery pack 40 is connected to the charger 4 with a charging cable and charged.

The battery pack 40 is connected to a motor 34 via a relay RY1 and an inverter 35. The inverter 35 converts DC electricity supplied from the battery pack 40 into AC electricity and supplies it to the motor 34 during powered operation. During regenerative operation, AC electricity supplied from the motor 34 is converted into DC electricity and supplied to the battery pack 40. The motor 34 is a three-phase AC motor, which rotates by means of the AC electricity supplied from the inverter 35 during powered operation. During regenerative operation, rotational energy due to deceleration is converted into AC electricity and supplied to the inverter 35.

The relay RY1 is a contactor inserted in wires connecting the battery pack 40 and the inverter 35. A vehicle control unit 30 is a vehicle ECU (Electronic Control Unit) that controls the entire electric motorcycle 3. During driving, the vehicle control unit 30 controls the relay RY1 to place it in an ON state (a closed state) and electrically connects the battery pack 40 and the power system of the electric motorcycle 3. When not driving, the vehicle control unit 30 controls the relay RY1 to place it in an OFF state (an open state) in principle and electrically disconnects the battery pack 40 and the power system of the electric motorcycle 3. Instead of a relay, another type of switch, such as a semiconductor switch, may be used.

The battery pack 40 includes a battery module 41 and a battery management unit 42. The battery module 41 includes multiple cells. FIG. 2 shows an illustrative configuration in which multiple cells E1 to En are connected in series. The configuration may also be provided such that multiple parallel cell blocks, which each are configured by multiple cells connected in parallel, are connected in series. For the cells, lithium-ion battery cells, nickel-metal hydride battery cells, lead-acid battery cells, and the like may be used. In the following, as an example, it will be assumed in the present specification that lithium-ion battery cells (nominal voltage: 3.6 to 3.7 V) are used. The number of cells E1 to En or parallel cell blocks connected in series is determined based on the drive voltage of the motor 34.

A shunt resistor Rs is connected in series with the multiple cells E1 to En or multiple parallel cell blocks. The shunt resistor Rs functions as a current sensing element. Instead of the shunt resistor Rs, a Hall element may be used. At multiple locations in the battery module 41, multiple temperature sensors T1 and T2 are provided to detect temperatures of the multiple cells E1 to En or multiple parallel cell blocks. For the temperature sensors T1 and T2, thermistors may be used, for example.

The battery management unit 42 includes a voltage measurement unit 43, a temperature measurement unit 44, a current measurement unit 45, a battery control unit 46, and a wireless communication unit 47. The connection points between the multiple cells E1 to En or multiple parallel cell blocks connected in series are respectively connected with the voltage measurement unit 43 by multiple voltage measurement lines. The voltage measurement unit 43 measures the voltage between each two adjacent voltage measurement lines, so as to measure voltages V1 to Vn of the respective cells E1 to En or the respective parallel cell blocks. The voltage measurement unit 43 transmits, to the battery control unit 46, the voltages V1 to Vn of the respective cells E1 to En or the respective parallel cell blocks thus measured.

Since the voltage measurement unit 43 has a higher voltage with respect to the battery control unit 46, the voltage measurement unit 43 and the battery control unit 46 are connected by a communication line in an insulated state. The voltage measurement unit 43 may be constituted by a general-purpose analog front-end IC or an ASIC (Application Specific Integrated Circuit). The voltage measurement unit 43 includes a multiplexer and an A/D converter. The multiplexer outputs, to the A/D converter, the voltages between two adjacent voltage lines in order from the top. The A/D converter converts the analog voltages input from the multiplexer into digital values.

The temperature measurement unit 44 includes voltage dividing resistors and an A/D converter. The A/D converter sequentially converts, into digital values, multiple analog voltages divided by means of the multiple temperature sensors T1 and T2 and multiple voltage dividing resistors and outputs the digital values to the battery control unit 46. Based on the multiple digital values, the battery control unit 46 measures the temperatures at multiple observation points in the battery module 41.

The current measurement unit 45 includes a differential amplifier and an A/D converter. The differential amplifier amplifies the voltage between both ends of the shunt resistor Rs and outputs it to the A/D converter. The A/D converter converts the analog voltage input from the differential amplifier into a digital value and outputs it to the battery control unit 46. Based on the digital value, the battery control unit 46 measures a current I flowing through the multiple cells E1 to En or multiple parallel cell blocks.

When an A/D converter is provided within the battery control unit 46 and an analog input port is also provided in the battery control unit 46, the temperature measurement unit 44 and the current measurement unit 45 may output the analog voltages to the battery control unit 46, and the analog voltages may be converted into digital values by means of the A/D converter within the battery control unit 46.

Based on the voltages, temperatures, and current of the multiple cells E1 to En or multiple parallel cell blocks measured by the voltage measurement unit 43, the temperature measurement unit 44, and the current measurement unit 45, the battery control unit 46 manages the states of the multiple cells E1 to En or multiple parallel cell blocks. If overvoltage, undervoltage, overcurrent, or a temperature abnormality occurs in at least one of the multiple cells E1 to En or multiple parallel cell blocks, the battery control unit 46 will turn off the protection relay (not illustrated) to protect the cell or parallel cell block.

The battery control unit 46 can be constituted by a microcontroller and a non-volatile memory {e.g., an EEPROM (Electrically Erasable Programmable Read-Only Memory) or a flash memory}. The battery control unit 46 estimates the SOC (State Of Charge) of each of the multiple cells E1 to En or multiple parallel cell blocks.

The battery control unit 46 estimates the SOC by combining the OCV method and the current integration method. The OCV method is a method of estimating the SOC based on the OCV of each cell measured by the voltage measurement unit 43 and the SOC-OCV curve of the cell. The SOC-OCV curve of the cell is created in advance based on characteristic tests performed by the battery manufacturer and is registered in the internal memory of the microcontroller at the time of shipment.

The current integration method is a method of estimating the SOC based on the OCV at the start of charging or discharging of each cell and the integrated value of the current measured by the current measurement unit 45. In the current integration method, the measurement errors of the current measurement unit 45 accumulate as the charging and discharging time increases. Meanwhile, the OCV method is affected by the measurement errors of the voltage measurement unit 43 and an error due to a polarization voltage. Therefore, it is preferable to use a weighted average of the SOC estimated by the current integration method and the SOC estimated by the OCV method.

The battery control unit 46 periodically (e.g., at intervals of 10 to 30 seconds) samples battery data including the voltage, current, temperature, and SOC of each of the cells E1 to En or parallel cell blocks and transmits the battery data to the data server 2 using the wireless communication unit 47. The wireless communication unit 47 includes a modem and performs wireless signal processing for wireless connection to the network 5 via an antenna 47a. For example, a cellular phone network (cellular network) is used to wirelessly connect to the network 5.

The wireless communication unit 47 and the antenna 47a may be provided on the main body side of the electric motorcycle 3. In that case, the battery control unit 46 transmits the sampled battery data to the vehicle control unit 30, which then transmits the battery data to the data server 2 using the wireless communication unit 47.

When the wireless communication unit 47 and the antenna 47a are not provided in the battery pack 40 or the main body of the electric motorcycle 3, at the time when the battery pack 40 is attached to or connected, with a charging cable, to a charger 4 having a network communication function, the battery control unit 46 transmits stored battery data to the charger 4. The charger 4 transmits the battery data thus received to the data server 2 via the network 5.

FIG. 3 is a diagram that shows an illustrative detailed configuration of voltage measurement systems between the battery module 41 and the voltage measurement unit 43 according to a comparative example. The connection points between multiple cells E1-E4, . . . or multiple parallel cell blocks connected in series are connected with the voltage measurement unit 43, respectively by multiple voltage measurement lines L0-L4, . . . . The voltage measurement unit 43 measures the voltage between each two adjacent voltage measurement lines, so as to measure the voltage of each of the cells E1-E4, . . . or each of the parallel cell blocks.

In the multiple voltage measurement lines L0-L4, . . . , resistors R0-R4, . . . are respectively inserted. Between each two adjacent voltage measurement lines of the multiple voltage measurement lines L0-L4, . . . , one of capacitors C1-C4, . . . is connected in parallel with the corresponding one of the multiple cells E1-E4, . . . or multiple parallel cell blocks. The resistors R0-R4, . . . and the capacitors C1-C4, . . . have a function as a low-pass filter that stabilizes each of the potentials of the multiple voltage measurement lines L0-L4, . . . .

In the comparative example, between each two adjacent voltage measurement lines of the multiple voltage measurement lines L0-L4, . . . , a discharge circuit is connected. The discharge circuits are constituted by series circuits that respectively include discharge switches S1d-S4d, . . . and discharge resistors R1d-R4d, . . . . For each of the discharge switches S1d-S4d, . . . , a MOSFET (Metal Oxide Semiconductor Field Effect Transistor) can be used, for example. The discharge circuits are mainly used for equalization processing for the multiple cells E1-E4, . . . or multiple parallel cell blocks.

In the equalization processing, among the multiple cells E1-E4, . . . or multiple parallel cell blocks, a cell or parallel cell block having the lowest voltage is specified, and the voltages of the other multiple cells or the other multiple parallel cell blocks are adjusted to the lowest voltage. In specific, the battery control unit 46 turns on the discharge switches of the other multiple cells or the other multiple parallel cell blocks to discharge the other multiple cells or the other multiple parallel cell blocks. When the voltage of each of the other cells or the other parallel cell blocks drops to the voltage of the cell or parallel cell block having the lowest voltage, the battery control unit 46 turns off the discharge switch of each of the other cells or the other parallel cell blocks.

In the comparative example, the battery control unit 46 sequentially turns on the discharge switches S1d-S4d, . . . at the time of startup or at all times, between voltage measurement times. By detecting a large voltage change between before and after the turn-on of a discharge switch, the battery control unit 46 detects the presence of abnormally high resistance on a voltage measurement line. Abnormally high resistance on a voltage measurement line means that there is a contact failure in the voltage measurement line.

Contact failures in the voltage measurement lines include: deterioration and disconnection of a wire harness; deterioration, loosening, and disengagement of a connector; deterioration, loosening, and disengagement of a terminal portion of the battery module 41; and deterioration, loosening, and disengagement of a terminal portion of the voltage measurement unit 43. The disconnection of a wire harness or the disengagement of a connector or a terminal is an irreversible contact failure, and hence, the insulation high resistance continues. On the other hand, the deterioration of a wire harness or the deterioration or loosening of a connector or a terminal is a reversible contact failure, so that the resistance value changes according to factors such as vibration and temperature changes. For example, a period of low resistance, during which normal conduction is performed, and a period of high resistance, during which normal conduction is disturbed, are switched according to external factors.

The example shown in FIG. 3 illustrates a state where there is a contact failure in the second voltage measurement line L2 connecting the connection point between the second cell E2 and the third cell E3 or between the second parallel cell block and the third parallel cell block, and the voltage measurement unit 43. In this case, the voltage between both ends of the second cell E2 and the third cell E3 or the voltage between both ends of the second parallel cell block and the third parallel cell block is measured as the total voltage value V2+V3 of the two cells or the two parallel cell blocks.

However, since the potential of the second voltage measurement line L2 is not fixed, the total voltage value V2+V3 of the two cells or the two parallel cell blocks is not necessarily divided into 1:1, and each of the voltage value V2 of the second cell E2 or the second parallel cell block and the voltage value V3 of the third cell E3 or the third parallel cell block becomes unstable. For example, at the moment when only the second discharge switch S2d is turned on, the potential of the second voltage measurement line L2 is attracted to the potential of the first voltage measurement line L1, and the voltage value V2 of the second cell E2 or the second parallel cell block is brought close to zero.

Discharge circuits for performing such equalization processing are usually installed in high-standard high-voltage battery packs 40 for EVs. On the other hand, in many of relatively low-voltage battery packs 40 installed in relatively inexpensive products, such as the electric motorcycles 3, discharge circuits for performing the equalization processing are not installed.

FIG. 4 is a diagram that shows an illustrative detailed configuration of voltage measurement systems between the battery module 41 and the voltage measurement unit 43 according to the embodiment. In the voltage measurement systems according to the embodiment shown in FIG. 4, the discharge switches S1d-S4d, . . . and the discharge resistors R1d-R4d, . . . shown in FIG. 3 are omitted. Therefore, a contact failure in the voltage measurement lines L0-L1, . . . cannot be detected by sequentially turning on the discharge switches S1d-S4d, . . . .

However, in the present embodiment, a contact failure in the voltage measurement lines L0-L1, . . . is detected by analyzing a fluctuation in each of the voltage measurements of the multiple cells E1-E4, . . . or multiple parallel cell blocks. That is, when a contact failure occurs in any of the voltage measurement lines L0-L1, . . . , the voltage measurements of the two adjacent cells or two adjacent parallel cell blocks located respectively above and below the voltage measurement line fluctuate unstably. By comparing this unstable voltage fluctuation with the voltage measurements of other normal cells or parallel cell blocks, a contact failure is detected.

FIG. 5 is a diagram that shows an illustrative configuration of the battery diagnosis system 1 according to the embodiment. The battery diagnosis system 1 includes a processing unit 11, a storage unit 12, and a communication unit 13. The communication unit 13 is a communication interface (e.g., NIC: Network Interface Card) for connecting to the network 5 by wired or wireless means.

The processing unit 11 includes a data acquirer 111, a representative value calculation unit 112, a score calculation unit 113, a judgment unit 114, and a notification unit 115. The functions of the processing unit 11 can be implemented by cooperation between hardware resources and software resources or only by hardware resources. As the hardware resources, CPUs, ROMS, RAMS, GPUs (Graphics Processing Units), ASICs (Application Specific Integrated Circuits), FPGAs (Field Programmable Gate Arrays), and other LSIs can be used. As the software resources, programs, such as operating system programs and application programs, can be used. The storage unit 12 includes a non-volatile recording medium, such as an HDD or SSD, and stores various data.

The data acquirer 111 acquires, from the data server 2, battery data of a battery pack 40 installed in an electric motorcycle 3. The battery data is time-series data that includes at least voltage data of multiple cells E1 to En or each parallel cell block in the battery pack 40.

Based on each of the acquired voltage values of the multiple cells E1 to En or multiple parallel cell blocks, the representative value calculation unit 112 calculates a representative value of the voltage data of the multiple cells E1 to En or multiple parallel cell blocks. For example, the representative value calculation unit 112 calculates, as the representative value, a median value or an average value of the voltage values of all of the multiple cells E1 to En or multiple parallel cell blocks. Also, the representative value calculation unit 112 may exclude the voltages of the two adjacent cells or two adjacent parallel cell blocks located respectively above and below a connection point connected with a voltage measurement line to be diagnosed and may calculate a median value or an average value of all remaining voltage values.

The score calculation unit 113 calculates difference values V1_diff to Vn_diff between the respective voltage values of the multiple cells E1 to En or multiple parallel cell blocks and the representative value thereof. The score calculation unit 113 performs temporal differentiation on the difference values V1_diff to Vn_diff thus calculated for the respective channels to calculate difference derivative values ΔV1_diff to ΔVn_diff for the respective channels. For example, the score calculation unit 113 calculates the difference derivative values ΔV1_diff to ΔVn_diff for the respective channels by subtracting, from the difference values V1_diff to Vn_diff for the respective channels at the target sampling timing, the corresponding difference values V1_diff to Vn_diff for the respective channels at the preceding sampling timing.

If the voltage measurement line of each channel is normal, the voltages of all cells or all parallel cell blocks will fluctuate equally even during charging or discharging of the battery pack 40, so that the difference derivative values ΔV_diff will be extremely small values. Also, even if the difference values V_diff are large due to the influence of the internal resistance differences or SOC differences between the multiple cells E1 to En or multiple parallel cell blocks, the amounts of time variation thereof, i.e., the difference derivative values ΔV_diff, will be extremely small values. In a battery pack 40 that is not equipped with the equalization processing function, SOC differences are likely to occur between the multiple cells E1 to En or multiple parallel cell blocks.

The score calculation unit 113 applies a low-pass filter to the difference derivative values ΔV1_diff to ΔVn_diff thus calculated for the respective channels to shape the difference derivative values ΔV1_diff to ΔVn_diff for the respective channels into smooth values. For example, the score calculation unit 113 calculates moving averages of the absolute values of the multiple difference derivative values ΔV1_diff to ΔVn_diff for the respective channels for a predetermined period of time (e.g., 10 minutes) and generates final difference derivative values ΔV1_diff_ave to ΔVn_diff_ave, which are to be compared with a judgment threshold th.

The difference derivative values ΔV1_diff_ave to ΔVn_diff_ave thus generated are used as judgment scores that represent relative fluctuations of the voltage measurements of the respective channels normalized by the fluctuation of the representative value. When the sampling period of the voltage data is short, the intensity of the low-pass filter may be reduced, or the low-pass filter may be omitted.

FIG. 6 is a diagram that shows actual measured data of voltage measurements and judgment scores of multiple parallel cell blocks. In the experiment, a battery pack 40 that contains 10 parallel cell blocks in series is used. In FIG. 6, three types of voltage measurements are plotted: the voltage value V2 of the second parallel cell block, the voltage value V3 of the third parallel cell block, and a median value MEDIAN. Also, three types of judgment scores are plotted: a judgment score Sv2 of the second parallel cell block, a judgment score Sv3 of the third parallel cell block, and a judgment score Sv1 of the first parallel cell block. The judgment scores of the other parallel cell blocks also show substantially the same behavior as the judgment score Sv1 of the first parallel cell block.

FIG. 7 is a diagram that shows another actual measured data of voltage measurements and judgment scores of the multiple parallel cell blocks. The actual measured data in FIG. 7 were obtained using the same battery pack 40 used in the experiment of FIG. 6. The actual measured data in FIG. 7 differ from the actual measured data in FIG. 6 in the observation period.

In both examples, the voltage value V2 of the second parallel cell block and the voltage value V3 of the third parallel cell block fluctuate to be vertically symmetrical with respect to the median value MEDIAN. In the example shown in FIG. 7, the voltage value V3 of the third parallel cell block contains a positive offset voltage, and the voltage value V2 of the second parallel cell block contains a negative offset voltage. In the example shown in FIG. 6, the voltage value V2 of the second parallel cell block and the voltage value V3 of the third parallel cell block scarcely contain any offset voltage.

When the judgment scores of two adjacent cells or two adjacent parallel cell blocks exceed a judgment threshold Sth, the judgment unit 114 judges that there is an abnormality in the voltage measurement system between the connection point of the two cells or the two parallel cell blocks and the voltage measurement unit 43. The judgment threshold Sth is set in advance based on at least one of the experimental results, simulation results, and designer's knowledge, regarding contact failures in the voltage measurement lines.

In both of the examples shown in FIGS. 6 and 7, the voltage value V2 of the second parallel cell block and the voltage value V3 of the third parallel cell block exceed the judgment threshold Sth, so that it is judged that there is an abnormality in the second voltage measurement line L2. Although the examples of FIGS. 6 and 7 show the actual measured data during charging, it has been confirmed that, also during discharging and downtime, the voltage value V2 of the second parallel cell block and the voltage value V3 of the third parallel cell block similarly fluctuate to be vertically symmetrical with respect to the median value MEDIAN.

When an abnormality in a voltage measurement system is detected, the notification unit 115 notifies an upper system of the abnormality in the voltage measurement system. The upper system is a system that detects an abnormality in the battery itself and estimates the remaining life of the battery. The upper system may be built in the same server as the voltage measurement system diagnosis system or may be built in another server. In the battery abnormality detection and the remaining life estimation, it is premised that correct voltage data have been acquired. If the reliability of the voltage data is low, the reliability of the battery abnormality detection and the remaining life estimation will also decrease. Upon receiving an abnormality in a voltage measurement system, the upper system stops or discards the results of the battery abnormality detection or the remaining life estimation based on the battery data during the period when the voltage measurement system has been abnormal. This can prevent the upper system from providing incorrect diagnostic results or notifying the user of incorrect diagnostic results.

When an abnormality in a voltage measurement system is detected, the notification unit 115 also notifies the user or administrator of the electric motorcycle 3 equipped with the subject battery pack 40, of the abnormality in the voltage measurement system via the network 5. For example, the notification unit 115 may transmit a control signal to the electric motorcycle 3 or the battery pack 40 to turn on an alert lamp of the electric motorcycle 3 or the battery pack 40. The notification unit 115 may also transmit an e-mail or a push notification to an information device (such as a PC or smartphone) of the user or administrator of the electric motorcycle 3.

FIG. 8 is a flowchart that shows a procedure of voltage measurement system diagnosis processing performed by the battery diagnosis system 1 according to the embodiment. The data acquirer 111 acquires, from the data server 2, battery data of a battery pack 40 installed in an electric motorcycle 3 (S10). The representative value calculation unit 112 calculates a representative value of voltage data of multiple parallel cell blocks included in the acquired battery data (S11). The score calculation unit 113 calculates a difference value between each of the voltage values of the multiple parallel cell blocks and the representative value (S12). The score calculation unit 113 performs temporal differentiation on each calculated difference value to calculate a difference derivative value (S13). The score calculation unit 113 calculates a moving average of the absolute value of each difference derivative value to calculate a judgment score of each channel (S14).

When the judgment scores of two adjacent channels both exceed a judgment threshold (Y at S15), the judgment unit 114 judges that the voltage measurement system between the connection point between the parallel cell blocks of the two adjacent channels and the voltage measurement unit 43 is abnormal (S16). When the judgment scores of two adjacent channels both do not exceed the judgment threshold (N at S15), the step S16 is skipped, and it is not judged that the voltage measurement system between the connection point between the parallel cell blocks of the two adjacent channels and the voltage measurement unit 43 is abnormal.

As described above, according to the present embodiment, an abnormality in a voltage measurement system of a battery pack 40 can be detected based on the voltage data of each channel. Since circuits for applying a current to the voltage measurement lines (e.g., discharge circuits for performing equalization processing) are not required, the hardware cost can be reduced. Also, the system can be used to detect an abnormality in a voltage measurement system of a relatively inexpensive battery pack 40 that is not equipped with an equalization processing function.

In the present embodiment, by differentiating the difference values with respect to the representative value, false detection due to the influence of the internal resistance differences or SOC differences can be prevented. When voltage measurements of a given channel contain an offset voltage, even if the voltage measurement system of the channel is normal, there is always a certain deviation between each of the voltage measurements of the two channels located respectively above and below the voltage measurement system and the representative value. That is, an abnormality in a voltage measurement system cannot be accurately determined only by observing the difference voltages with respect to the representative value. In this regard, in the present embodiment, by observing the changes in the difference voltages with respect to the representative value, an abnormality in a voltage measurement system can be determined with high accuracy even when the voltage measurements contain an offset voltage as shown in FIG. 7.

When the voltage measurement timing of each parallel cell block is simultaneous, the voltage measurements of the two channels located respectively above and below an abnormal voltage measurement system fluctuate to be vertically symmetrical with respect to the median value, as shown in FIGS. 6 and 7. Meanwhile, when the voltage measurement timing is different or when the timing of transmission to the data server 2 is different for each channel, the voltage measurements of the two channels located respectively above and below an abnormal voltage measurement system may not be vertically symmetrical. In this regard, in the present embodiment, since the changes in the difference voltages with respect to the representative value are observed, vertical symmetry is not required. That is, even when the sampling timing of the voltage measurement is different among multiple channels, an abnormality in a voltage measurement system can be determined with high accuracy.

In the present embodiment, the influence of noise can be removed by using moving average values of the difference derivative values with respect to the representative value. Also, judgment can be made in which the influence of voltage changes between two adjacent sampling times is considered. For example, even though the voltage measurements fluctuate greatly during the period between two adjacent sampling times, if the voltage measurements at the two sampling times happen to be the same, the difference derivative value will be zero. In the present embodiment, by using moving average values of the differential derivative values, the trend of changes in the difference derivative values can be accurately grasped.

The present disclosure has been described with reference to an embodiment. The embodiment is intended to be illustrative only, and it will be obvious to those skilled in the art that various modifications to a combination of constituting elements or processes could be developed and that such modifications also fall within the scope of the present disclosure.

In the aforementioned embodiment, an example has been described in which, with the battery diagnosis system 1 connected to the network 5, an abnormality in a voltage measurement system of a battery pack 40 installed in an electric motorcycle 3 is detected. In this regard, the battery diagnosis system 1 may be incorporated into the battery control unit 46.

Also, the use of the battery diagnosis system 1 according to the present disclosure is not limited to the detection of an abnormality in a voltage measurement system of a battery pack 40 installed in an electric motorcycle 3. For example, it can also be used for detection of an abnormality in a voltage measurement system of a battery pack 40 installed in an electric bicycle or an information device (e.g., a notebook PC, a tablet, or a smartphone).

In the aforementioned embodiment, an example of the battery pack 40 that is not equipped with an equalization processing function has been described; however, the battery diagnosis system 1 according to the present disclosure can also be used for detection of an abnormality in a voltage measurement system of a battery pack 40 equipped with an equalization processing function. Therefore, the battery diagnosis system 1 according to the present disclosure can also be used for detection of an abnormality in a voltage measurement system of a battery pack 40 installed in an electric vehicle (an EV, an HEV, or a PHEV), an electric ship, a multicopter (drone), a stationary electricity storage system, or the like.

The embodiment may be defined by the following Items.

### [Item 1]

A voltage measurement system diagnosis system (1), including:
a data acquirer (111) that acquires voltage data of each cell of a battery pack (40) in which multiple cells (E1-En) are connected in series or voltage data of each parallel cell block of a battery pack (40) in which parallel cell blocks, which each include multiple cells connected in parallel, are connected in series; and
a judgment unit (114) that judges, when a fluctuation in a voltage of each of two cells adjacent among the multiple cells (E1-En) or two parallel cell blocks adjacent among the multiple parallel cell blocks exceeds a threshold, that there is an abnormality in a voltage measurement system between a connection point of the two cells or the two parallel cell blocks and a voltage measurement unit (43).

According to this, an abnormality in a voltage measurement system of the battery pack (40) can be detected at low cost.

### [Item 2]

The voltage measurement system diagnosis system (1) according to Item 1, further including:
a representative value calculation unit (112) that calculates a representative value of voltage data of the multiple cells (E1-En) or the multiple parallel cell blocks, based on each of voltage values of the multiple cells (E1-En) or the multiple parallel cell blocks; and
a score calculation unit (113) that calculates each of difference values between the respective voltage values of the multiple cells (E1-En) or the multiple parallel cell blocks and the representative value and also calculates, as a score representing the fluctuation, each of difference derivative values obtained by performing temporal differentiation on the difference values calculated.

According to this, the influence of offsets or differences in sampling timing can be removed by using the difference derivative values with respect to the representative value.

### [Item 3]

The voltage measurement system diagnosis system (1) according to Item 2, wherein the score calculation unit (113) uses a difference derivative value obtained by applying a low-pass filter to a difference derivative value calculated, as a value to be compared with the threshold.

According to this, the influence of noise can be reduced. Also, judgment can be made in which the influence of voltage changes in a period between two adjacent sampling times is considered.

### [Item 4]

The voltage measurement system diagnosis system (1) according to Item 2 or 3, wherein the representative value calculation unit (112) calculates, as the representative value, a median value or an average value of: the voltage values of all of the multiple cells (E1-En) or the multiple parallel cell blocks; or all voltage values except the voltage values of the two cells or the two parallel cell blocks.

According to this, the voltage value of each cell or each parallel cell block can be normalized with high accuracy.

### [Item 5]

A voltage measurement system diagnosis method, including:
acquiring voltage data of each cell of a battery pack (40) in which multiple cells (E1-En) are connected in series or voltage data of each parallel cell block of a battery pack (40) in which parallel cell blocks, which each include multiple cells (E1-En) connected in parallel, are connected in series; and
judging, when a fluctuation in a voltage of each of two cells adjacent among the multiple cells (E1-En) or two parallel cell blocks adjacent among the multiple parallel cell blocks exceeds a threshold, that there is an abnormality in a voltage measurement system between a connection point of the two cells or the two parallel cell blocks and a voltage measurement unit (43).

According to this, an abnormality in a voltage measurement system of the battery pack (40) can be detected at low cost.

### [Item 6]

A voltage measurement system diagnosis program causing a computer to implement:
acquiring voltage data of each cell of a battery pack (40) in which multiple cells (E1-En) are connected in series or voltage data of each parallel cell block of a battery pack (40) in which parallel cell blocks, which each include multiple cells (E1-En) connected in parallel, are connected in series; and
judging, when a fluctuation in a voltage of each of two cells adjacent among the multiple cells (E1-En) or two parallel cell blocks adjacent among the multiple parallel cell blocks exceeds a threshold, that there is an abnormality in a voltage measurement system between a connection point of the two cells or the two parallel cell blocks and a voltage measurement unit (43).

According to this, an abnormality in a voltage measurement system of the battery pack (40) can be detected at low cost.

1. A voltage measurement system diagnosis system, comprising:
a data acquirer that acquires voltage data of each cell of a battery pack in which a plurality of cells are connected in series or voltage data of each parallel cell block of a battery pack in which parallel cell blocks, which each include a plurality of cells connected in parallel, are connected in series; and
a judgment unit that judges, when a fluctuation in a voltage of each of two cells adjacent among the plurality of cells or two parallel cell blocks adjacent among the plurality of parallel cell blocks exceeds a threshold, that there is an abnormality in a voltage measurement system between a connection point of the two cells or the two parallel cell blocks and a voltage measurement unit.

2. The voltage measurement system diagnosis system according to claim 1, further comprising:
a representative value calculation unit that calculates a representative value of voltage data of the plurality of cells or the plurality of parallel cell blocks, based on each of voltage values of the plurality of cells or the plurality of parallel cell blocks; and
a score calculation unit that calculates each of difference values between the respective voltage values of the plurality of cells or the plurality of parallel cell blocks and the representative value and also calculates, as a score representing the fluctuation, each of difference derivative values obtained by performing temporal differentiation on the difference values calculated.

3. The voltage measurement system diagnosis system according to claim 2,
wherein the score calculation unit uses a difference derivative value obtained by applying a low-pass filter to a difference derivative value calculated, as a value to be compared with the threshold.

4. The voltage measurement system diagnosis system according to claim 2, wherein the representative value calculation unit calculates, as the representative value, a median value or an average value of: the voltage values of all of the plurality of cells or the plurality of parallel cell blocks; or all voltage values except the voltage values of the two cells or the two parallel cell blocks.

5. A voltage measurement system diagnosis method, comprising:
acquiring voltage data of each cell of a battery pack in which a plurality of cells are connected in series or voltage data of each parallel cell block of a battery pack in which parallel cell blocks, which each include a plurality of cells connected in parallel, are connected in series; and
judging, when a fluctuation in a voltage of each of two cells adjacent among the plurality of cells or two parallel cell blocks adjacent among the plurality of parallel cell blocks exceeds a threshold, that there is an abnormality in a voltage measurement system between a connection point of the two cells or the two parallel cell blocks and a voltage measurement unit.

6. A non-transitory computer-readable recording medium having embodied thereon a voltage measurement system diagnosis program causing a computer to implement:
acquiring voltage data of each cell of a battery pack in which a plurality of cells are connected in series or voltage data of each parallel cell block of a battery pack in which parallel cell blocks, which each include a plurality of cells connected in parallel, are connected in series; and
judging, when a fluctuation in a voltage of each of two cells adjacent among the plurality of cells or two parallel cell blocks adjacent among the plurality of parallel cell blocks exceeds a threshold, that there is an abnormality in a voltage measurement system between a connection point of the two cells or the two parallel cell blocks and a voltage measurement unit.
